(19) United States
(12) Patent Application Publication
(10) Pub. No.: US 2025/0284861 A1
(43) Pub. Date: Sep. 11, 2025

(54) TRACKING INSOLATION ON SOLAR PANELS

(71) Applicant: Robert BOOKMAN, Stone Mountain, GA (US)

(72) Inventor: Robert BOOKMAN, Stone Mountain, GA (US)

(21) Appl. No.: 19/072,509

(22) Filed: Mar. 6, 2025

Related U.S. Application Data
(60) Provisional application No. 63/561,825, filed on Mar. 6, 2024.

(51) Int. Cl. G06F 30/20

(52) U.S. Cl. CPC G06F 30/20

(57) ABSTRACT

A method for designing and building a photovoltaic solar system and collector at a predetermined location includes calculating a daily average TMY insolation value from TMY data for a predetermined orientation of the collector, calculating a daily average shading insolation loss value from one or more shading obstructions, calculating a daily average temperature derating insolation loss value, calculating a daily average effective insolation value by subtracting the shading loss value and the derating loss value from the TMY insolation value, determining a minimum energy output requirement for the PV solar system, determining a minimum required PV area for the collector based on the minimum energy output requirement and the daily average effective insolation value, and building the PV solar system at the predetermined location with the collector at the predetermined orientation. The collector has at least the minimum required PV area.

### CROSS REFERENCE TO RELATED APPLICATIONS

This application claims the benefit of U.S. Provisional Patent Application No. 63/561,825, filed Mar. 6, 2024, entitled “Tracking Insolation on Solar Panels,” the entire contents of which are incorporated by reference herein.

### BACKGROUND

Embodiments described herein relate generally to solar panel installation, and more particularly, to a method of designing and building a solar panel that reliably meets energy needs.

Global demand for energy has reached unprecedented levels over the past decades. The need to reduce greenhouse gases, a cause of global warming resulting from burning fossil fuels to meet energy demands, has driven the global focus toward utilizing renewable, sustainable and cleaner alternative energy sources. Atmospheric carbon dioxide (CO₂) concentrations have increased sharply since the 1870s due to a constant increased burning of fossil fuels, a consequence of the Industrial Revolution. This increased activity is responsible for most of the global warming over the past fifty years. Because natural processes cannot quickly remove CO₂ from the atmosphere, future emissions, if allowed to continue, will influence the climate system for millennia.

Solar energy stands out as the most promising form of renewable energy available to stem the global energy demand and reduce greenhouse gases. First, solar energy is clean and produces electricity without emitting greenhouse and toxic gases such as CO₂ and nitrogen oxide (NOx). Second, economically, solar energy offers a positive effect after the initial investment, translating into reduced electricity bills and potential new jobs. Third, solar is relatively easy to install on rooftops of commercial buildings, while producing clean electricity.

Buildings, including commercial and residential properties account for approximately 40% of global energy consumption and play an important role in the energy market. These buildings provide crucial facilities for human needs and while their countless benefits to society cannot be ignored, buildings supplied by fossil fuel for heating, cooling, and lighting generate destructive influences on the environment. The future outcome of human-generated climate change from fossil fuels by the turn on this century involves both high risk and high uncertainty. To do our part for global civilization, as we know it, to continue to thrive, it is imperative that we strongly consider implementing alternative energy sources such as solar energy as a renewable, economic, and sustainable energy technology replacement for fossil fuels.

The potential for solar energy use is dependent upon the amount of sun shining on the earth's surface, known as solar insolation. Several factors, such as weather patterns, humidity, and haze can affect local insolation levels. However, there is currently no simplified method for designing and building a feasible and economical photovoltaic (PV) solar system, that can take into account insolation and various factors impacting insolation to reliably construct an adequately sized and oriented system to match power output requirements.

### BRIEF SUMMARY

Briefly stated, one example embodiment comprises a method for designing and building a photovoltaic (PV) solar system at a predetermined location, wherein the PV solar system includes at least one collector. The method includes calculating a daily average typical meteorological year (TMY) insolation value from TMY data for a predetermined orientation of the at least one collector of the PV solar system, calculating a daily average shading insolation loss value for the predetermined location resulting from one or more shading obstructions and the predetermined orientation of the at least one collector of the PV solar system, calculating a daily average temperature derating insolation loss value at the predetermined location, calculating a daily average effective insolation value for the predetermined location and predetermined orientation of the at least one collector of the PV solar system by subtracting the daily average shading insolation loss value and the daily average temperature derating insolation loss value from the daily average TMY insolation value, determining a minimum energy output requirement for the PV solar system, determining a minimum required PV area for the at least one collector of the PV solar system based on the minimum energy output requirement and the daily average effective insolation value, and building the PV solar system at the predetermined location with the at least one collector at the predetermined orientation. The at least one collector of the PV solar system has at least the minimum required PV area.

In one aspect, the TMY data includes at least Global Horizontal Irradiance (GHI), Direct Normal Irradiance (DNI), and Diffuse Horizontal Irradiance (DHI) for a latitude and longitude of the predetermined location on at least one selected day of the year at one or more selected hours of the selected day. In a further aspect, calculating the daily average TMY insolation value includes calculating a total radiation on the at least one collector I_{C} by summing a direct beam radiation I_{BC} on the at least one collector, a diffused radiation I_{DC} on the at least one collector, and a reflected radiation I_{RC} on the at least one collector, wherein I_{BC} is dependent upon DNI, I_{DC} is dependent upon DHI, and I_{RC} is dependent upon GHI.

In another aspect, the predetermined orientation of the at least one collector of the PV solar system is a fixed orientation wherein the at least one collector fixedly faces a single, predetermined direction and is fixedly angled with respect to a local horizon at a predetermined collector tilt angle.

In still another aspect, the predetermined orientation of the at least one collector of the PV solar system is a one-axis track, wherein the PV solar system moves the at least one collector in a single axis to track a position of the sun in a generally east-west trajectory.

In yet another aspect, the predetermined orientation of the at least one collector of the PV solar system is a two-axis track, wherein the PV solar system moves the at least one collector in two axes to track a position of the sun in a generally east-west trajectory and a generally north-south trajectory.

In another aspect, calculating the daily average shading insolation loss value includes: determining an azimuth angle and altitude angle for each of the one or more shading obstructions, and determining one or more time periods, by comparing the azimuth angle and altitude angle of each of the one or more shading obstructions to a sun path for the predetermined location on at least one selected day of the year for one or more selected hours of the selected day, in which the at least one collector of the PV solar system is blocked by shading from each of the one or more shading obstructions.

In yet another aspect, calculating the daily average temperature derating insolation loss value is based on at least a nominal operating cell temperature (NOCT) of the at least one collector and ambient temperature for the predetermined location on at least one selected day of the year for one or more selected hours of the selected day.

### BRIEF DESCRIPTION OF THE SEVERAL VIEWS OF THE DRAWINGS

The following detailed description of preferred embodiments will be better understood when read in conjunction with the appended drawings. For the purpose of illustration, there are shown in the drawings embodiments which are presently preferred. It should be understood, however, that the invention is not limited to the precise arrangements and instrumentalities shown.

In the drawings:

FIG. 1 is a flow diagram of an example method in accordance with an embodiment of the present invention;

FIG. 2 is a schematic diagram of an example PV solar system built in accordance with the method of FIG. 1; and

FIG. 3 is an example comparison of shading obstructions with a sun path as part of the method of FIG. 1.

### DETAILED DESCRIPTION

Certain terminology is used in the following description for convenience only and is not limiting. The words “right”, “left”, “lower”, and “upper” designate directions in the drawings to which reference is made. The words “inwardly” and “outwardly” refer to directions toward and away from, respectively, the geometric center of the device and designated parts thereof. The terminology includes the above-listed words, derivatives thereof, and words of similar import. Additionally, the words “a” and “an”, as used in the claims and in the corresponding portions of the specification, mean “at least one.”

It should also be understood that the terms “about,” “approximately,” “generally,” “substantially” and like terms, used herein when referring to a dimension or characteristic of a component, indicate that the described dimension/characteristic is not a strict boundary or parameter and does not exclude minor variations therefrom that are functionally similar. At a minimum, such references that include a numerical parameter would include variations that, using mathematical and industrial principles accepted in the art (e.g., rounding, measurement or other systematic errors, manufacturing tolerances, etc.), would not vary the least significant digit.

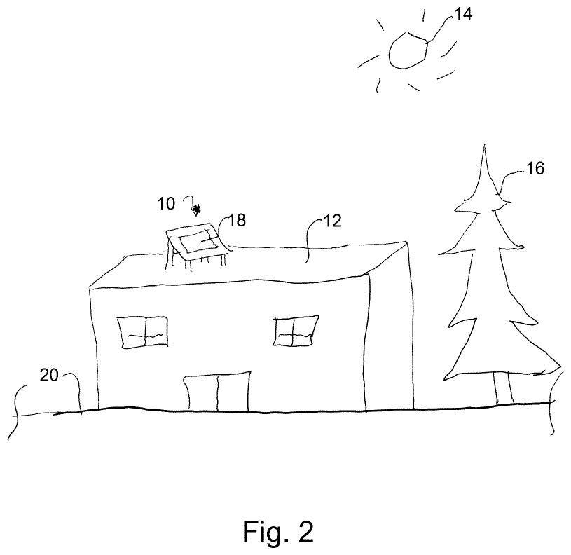

FIG. 2 is a schematic diagram of an example PV solar system 10 that may be designed and built at a predetermined location in accordance with embodiments of the present invention. The PV solar system 10 is shown mounted on a rooftop of a facility 12 for which the PV solar system 10 may be providing generated power from exposure to sun 14. Although shown mounted on the roof of facility 12, the PV solar system 10 may also be a ground-mounted system, or could be mounted on the roof of adjacent buildings or other structures. In particular, the PV solar system 10 may be designed and built while accounting for the typical expected daily insolation from the sun 14, losses expected to nearby shading obstructions, such as tree 16 or the like, and losses due to temperature impacted operation of one or more collectors 18 of the PV solar system 10.

The PV solar system 10 may have a predetermined orientation of which there are generally three main categories. The first is a fixed orientation wherein the at least one collector 18 fixedly faces a single, predetermined direction (e.g., south, or the like) and is fixedly angled with respect to a local horizon 20 at a predetermined collector tilt angle. The direction and tilt angle are generally chosen to maximize exposure to the sun 14 as it tracks overhead. As explained in further detail below, the method for determining daily average effective insolation may aid in selecting the direction and tilt angle of the collector(s) 18. The fixed orientation is typically the least expensive of the mounting types for a PV solar system since moving parts and motors are unnecessary.

A second type of orientation category is a one-axis track, wherein the PV solar system 10 moves the collector 18 in a single axis to track a position of the sun 14 in a generally east-west trajectory. This motion allows more direct insolation from the sun 14 as it moves across the sky, resulting in a higher power yield and increased efficiency. However, such one-axis PV solar systems 10 involve higher initial costs due to the moving parts and energy required to run the motor(s) moving the collector 18 over the course of the day. This type will also have maintenance costs for keeping the moving parts functional later in life. A third type of orientation category is a two-axis track, wherein the PV solar system 10 moves the collector 18 in two axes to track a position of the sun 14 in a generally east-west trajectory and a generally north-south trajectory. Since over the course of the year the direction of the sun 14 changes, a two-axis system maximizes power yield and efficiency by being able to directly face the sun 14 at all times thanks to the extra degree of freedom in motion. However, this technology is also the most expensive. It is contemplated that when designing a PV solar system 10, cost may be considered in choosing the predetermined orientation thereof.

Various types of collectors 18 may be considered as well, and some of the characteristics thereof are utilized in the method described below for designing the overall PV solar system 10. Monocrystalline (single crystal) collectors have the highest efficiency rating among solar cells, accounting for its construction with high-grade silicon. The advantage of single-crystal construction is the ability for electrons within the crystal to have increased capacity to roam, yielding greater electron-hole pairings and increased photovoltaic conversion, leading to a higher flow of current, resulting in greater overall efficiency. The technology typically converts greater than 21% of sunlight into electricity and is more efficient than polycrystalline collectors. Owing to the high purity of the material, however, monocrystalline systems are also the most expensive.

Polycrystalline (p-Si) collectors have a lower price point than the monocrystalline technology. However, the p-Si technology typically offers lower efficiency (˜15%), is less heat tolerant, requires a larger surface area to output the same electrical power as the mono-Si technology, and offers lower silicon purity than its rival. The p-Si technology embeds multiple fragments of silicon crystal in each cell, causing less freedom for electrons to move around, resulting in reduced efficiency. The p-Si collector does, however, rival the monocrystalline collector in longevity.

The amorphous (a-Si) collector technology has a matured status of twenty-plus years of use in commercial space for powering LED lighting. The low manufacturing costs of the amorphous cell makes this collector highly cost competitive. The drawback with a-Si technology tends to be its unstructured glassy silicon construction that provides limited order to the arrangement of atoms in the cell. This produces an unstable electron that fails to bond (“dangling bonds”). The unstable electron falls back into the valence band after being excited by a photon, before it can be harvested for conversion into useful energy. This drawback causes the technology to have a low efficiency rating of approximately 9%.

Cadmium telluride (CdTe) collectors are the second-most used technology behind silicon and include of thin film technology that absorbs and converts photons into electricity. This technology leverages two types of cadmium molecules, cadmium sulfide and cadmium telluride, to achieve the required properties for photon conversion, resulting in less material required for production. A potential drawback to this technology is its ranking as one of the top six deadliest toxic materials known. Presently in the U.S., the most common opinion is that the use of Cadmium Telluride in residential and industrial rooftop solar installation does not pose a major environmental threat.

Thin-film collectors are a second-generation technology that is made by depositing one, or several layers of thin-film on a substrate, such as glass, plastic, or metal. This technology is used commercially in its competitor's technologies, including CdTe, amorphous (a-Si) and thin-film silicon (TF-Si). This technology typically has flexibility and low comparative cost.

Concentrated PV (CPV) collectors are used by large electric generators such as the Georgia Power Company to achieve high efficiency conversion of solar radiation into electricity but can be scaled for use by commercial applications. The CPV includes an advanced optical system of highly magnified lenses and curved mirrors that are used to convert solar energy into electrical energy with an efficiency of 41%. This technology requires high-performance trackers that intelligently and automatically track the sun throughout the day. Although highly efficient, the initial capital costs, operating and manufacturing costs, and space requirements for mounting can be prohibitive.

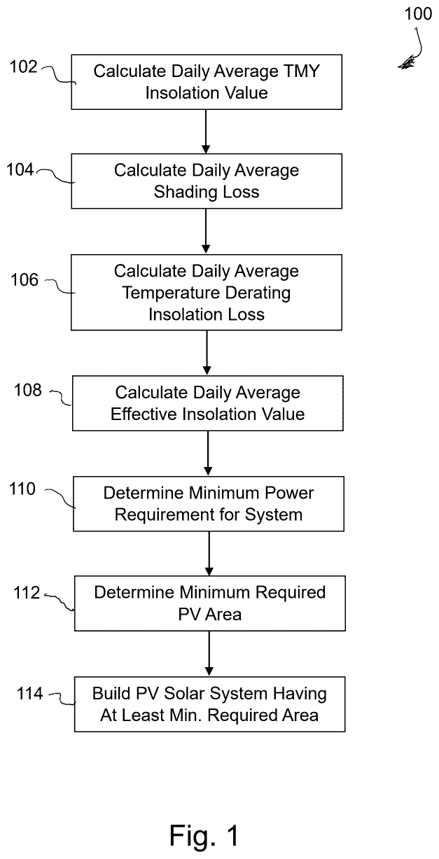

FIG. 1 is a flow chart showing an example embodiment of a method 100 for designing and building a PV solar system 10 such as that shown in FIG. 2. An initial step in the method 100 may be to perform a physical site assessment to determine the solar radiation potential for the site, to identify potential sun path obstacles that could cause shading and a corresponding loss of solar insolation to the solar system, and to identify the ideal on-site location for siting the PV solar system. The site assessment may also determine the feasibility of ground mounted solar versus rooftop panels. Building and site measurements and building roof slope (if necessary) may be obtained from existing or future site plans and/or direct measurements. For example, building area, facility area, and roof slope may be obtained. A suitable ground or facing roof available for PV solar system, particularly one allowing for the sun's maximum irradiation exposure, may be measured.

Latitudinal and longitudinal coordinates for the predetermined location are also preferably obtained. For example, coordinate may be obtained using a hand-held true-north compass to avoid the task of making corrections to the difference between true-north and magnetic north readings. Azimuth and altitude angles of potentially shading obstructions on site may similarly be obtained using a true-north compass and a hand-held magnetic protractor angle locator.

At step 102, a daily average typical meteorological year (TMY) insolation value may be calculated from TMY data for a predetermined orientation of the at least one collector of the PV solar system. TMY data that may be used here to determine the effective insolation available on the at least one collector may provide “real-time” site-specific, hour-by-hour estimates of both normal (perpendicular) and horizontal (relative to earth's surface) extraterrestrial irradiation (ETRN ETR), Global Horizontal Irradiance (GHI), Direct Normal Irradiance (DNI), and Diffuse Horizontal Irradiance (DHI), and may further considers important factors such as wind speed, temperature, humidity, illuminance, and precipitation that affect the amount of insolation that is available on the at least one collector. As one example, TMY data may be retrieved for specific locations at the National Solar Radiation Database (NSRDB) Data Viewer. Following retrieval of the necessary TMY data, hour-by-hour, monthly, and/or annual TMY insolation may be calculated using one or more orientations of the at least one collector of the planned PV solar system. For example, multiple collector azimuth and tilt angles may be tested to identify the optimum azimuth and tilt orientations for maximum insolation exposure on the collector.

The following equations may be used for a fixed orientation collector:

$${I}_{BC} = {I}_{B} cos θ ( for all orientations )$$

$$cos θ = cos β cos ( {φ}_{c} - {φ}_{s} ) sin Σ + sin β cos Σ$$

$$C = 0. 095 + 0.04 sin [ 360 / 365 ( n - 100 ) ]$$

$${I}_{DC} = {I}_{B} C ( 1 + cos Σ ) / 2$$

$${I}_{RC} = {I}_{B} ρ ( C + sin β ) ( 1 - cos Σ ) / 2$$

$${I}_{C} = {I}_{BC} + {I}_{DC} + {I}_{RC}$$

wherein I_{BC} is direct beam radiation on the collector, I_{DC} is diffused radiation, scattered by atmospheric particles and moisture or reflected form clouds, on the collector, I_{RC} is radiation received by the collector that has reflected from surfaces surrounding the collector, I_{C} is total radiation on the collector, I_{B} is the incoming clear beam radiation that reaches a point on earth's surface, θ is the angle of incidence as a function of the collector orientation, β is the solar altitude angle, φₛ is the solar azimuth angle, φ_{c} is the collector azimuth angle, Σ is the tilt angle of the collector, C is a sky diffuse factor used in Threkeld and Jordan equations, n is a day of the given month, and p is a ground reflectance factor (0 to 1.0).

The equations may change for a one-axis track collector, depending on whether the orientation is horizontal north-south (HNS) or horizontal east-west (HEW):

$$cos θ = √ [ 1 - {( cos β / cos {φ}_{s} )}^{2} ] ( HNS )$$

$$cos θ = √ [ 1 - {( cos β / sin {φ}_{s} )}^{2} ] ( HEW )$$

$${I}_{BC} = {I}_{B} cos θ$$

$${I}_{DC} = {I}_{B} C [ 1 + ( sin β / cos θ ) ] / 2$$

$${I}_{RC} = {I}_{B} ρ ( C + sin β ) [ 1 - ( sin β / cos θ ) ] / 2$$

$${I}_{C} = {I}_{BC} + {I}_{DC} + {I}_{RC}$$

and for a two-axis track collector:

$$cos θ = 1$$

$${I}_{B C} = {I}_{B}$$

$${I}_{DC} = {I}_{B} C ( 1 + sin β ) / 2$$

$${I}_{RC} = {I}_{B} ρ ( C + sin β ) ( 1 - sin β ) / 2$$

$${I}_{C} = {I}_{BC} + {I}_{DC} + {I}_{RC}$$

It is possible to substitute I_{B} with the aforementioned DNI TMY data, so that I_{BC}=DNI cos θ. In addition, the factor I_{B} C may be substituted by DHI, and the factor I_{B} ρ may be substituted for GHI ρ for purposes of calculating the total insolation I_{C}.

The daily average TMY insolation value may be calculated by obtaining a sum of total TMY insolation for the year (or some fraction thereof) and dividing by the number of corresponding days. For example, the table below shows daily TMY insolation calculated for the 21st day of each month for various tilt angles of a fixed orientation collector at a specified location. The yearly total TMY insolation may be determined from this data by multiplying each daily TMY insolation by the number of days in the corresponding month and adding the results together for the full year. The total insolation is highest at 1874 kWh/m²/yr for a tilt angle of 22.62° at the predetermined location in this example. By dividing the total TMY insolation by 365, a daily average TMY insolation value of 5.13 kWh/m²/day. However, other methods of determining a daily average may be used as well. For example, a different representative day for each month may be utilized, multiple days per month may be utilized, fewer months may be selected, and the like.

Daily TMY Insolation (kWh/m2/d) (21^{st} Day of each Month)

| | | Azim: | | | | | | | |
|---|---|---|---|---|---|---|---|---|---|
| | | S | | | | | | | |
| Tilt: | 0° | 20 | 22.62 | 36 | Lat | 40 | 50 | 60 | 90 |
| January | 1.8 | 2.0 | 2.0 | 2.0 | 2.0 | 2.0 | 2.0 | 1.9 | 1.6 |
| February | 2.5 | 2.7 | 2.8 | 2.8 | 2.8 | 2.8 | 2.7 | 2.7 | 2.1 |
| March | 5.7 | 6.2 | 6.3 | 6.3 | 6.3 | 6.3 | 6.1 | 5.8 | 4.3 |
| April | 5.8 | 5.9 | 5.9 | 5.8 | 5.7 | 5.6 | 5.3 | 4.9 | 3.4 |
| May | 5.3 | 5.2 | 5.2 | 5.1 | 5.0 | 4.9 | 4.6 | 4.3 | 3.1 |
| June | 7.7 | 7.5 | 7.5 | 7.2 | 7.0 | 6.7 | 6.1 | 5.4 | 2.9 |
| July | 7.4 | 7.4 | 7.4 | 7.2 | 7.0 | 6.8 | 6.2 | 5.6 | 3.2 |
| August | 6.7 | 7.0 | 7.0 | 6.9 | 6.9 | 6.7 | 6.4 | 5.9 | 3.8 |
| September | 5.7 | 6.2 | 6.3 | 6.3 | 6.3 | 6.3 | 6.1 | 5.8 | 4.2 |
| October | 4.4 | 5.2 | 5.3 | 5.5 | 5.5 | 5.6 | 5.6 | 5.5 | 4.5 |
| November | 3.2 | 4.0 | 4.1 | 4.3 | 4.4 | 4.5 | 4.6 | 4.6 | 4.1 |
| December | 1.3 | 1.6 | 1.7 | 1.7 | 1.8 | 1.9 | 1.9 | 1.9 | 1.7 |
| Total | 1633 | 1742 | 1874 | 1754 | 1745 | 1826 | 1671 | 1586 | 1170 |
| (kWh/m²/yr) | | | | | | | | | |

At step 104, a daily average shading insolation loss value is calculated for the predetermined location resulting from one or more shading obstructions and the predetermined orientation of the at least one collector of the PV solar system. First, the potential shading obstructions may be identified, such as, for example, trees, buildings, hills, or the like. For each such shading obstruction, an azimuth angle and an altitude angle may be determined, such as in the manner described above. The table below summarizes this information for tree buffer zones that were found as potential shading obstructions at the example predetermined location described above.

Tree Buffer Zones (LWSC)

| | Azimuth | Altitude |
|---|---|---|
| | angle | angle |
| Tree Line (Due South of LWSC) | 0° | 31° |
| Tree Line (East to Due-South of LWSC) | 90° to 0° | 31° |
| Tree Line (Due South to West of LWSC) | 0° to (−90°) | 31° |

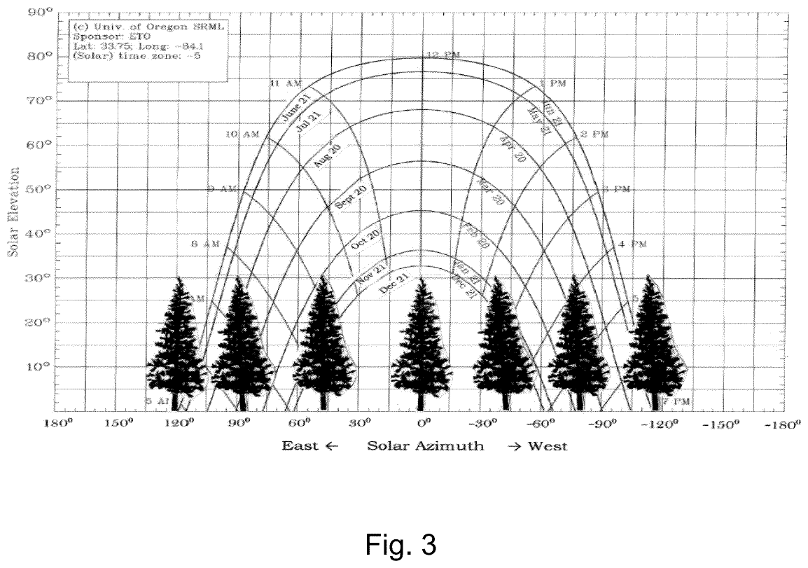

The possible shading obstructions may be compared to a sun path for the predetermined location on at least one selected day of the year for one or more selected hours of the selected day. FIG. 3 shows an example comparison of the aforementioned tree obstructions being overlaid on a sun path diagram that shows the solar altitude and azimuth for given months and times. From such a comparison, one or more time periods may be determined in which the collector is obscured from the sun by one of the shading obstructions. In the example provided, it could be determined that the trees obstruct the collector between 6-10 AM and 1:45-6 PM on January 21. From the TMY insolation analysis, the hourly insolation during these time periods can be summed to determine how much insolation ends up being blocked by the shading obstructions during these time periods. This analysis may be repeated in various ways to obtain a daily average shading insolation loss value for the predetermined location, such as by sampling various days over the course of the year to estimate a yearly shading insolation loss that is divided by the number of days, although other techniques for analyzing the information to obtain the daily average shading insolation loss value may be used as well. In the example provided, a daily average shading insolation loss of 1.48 kW/m²/day was found.

In some embodiments, it may be possible to determine that a collector may only be partially obscured by a shading obstruction during certain time periods. In such cases, it may be possible to calculate a percentage of the corresponding hourly TMY insolation amounts, for example, that reflects the portion of the collector area that is obscured.

At step 106, a daily average temperature derating insolation loss value is calculated at the predetermined location. Derate factors may be used to account for insolation loss due to solar cells operating at temperatures above or below the manufacturer's established nominal operating cell temperature (NOCT). NOCT is the expected cell temperature in a module when ambient temperature is 20° C., solar irradiation is 0.8 kW/m2, and wind speed is 1 m/s. The following equation may be used to determine the cell temperature that is necessary to compute the temperature derate factor for a collector:

$${T}_{cell} = {T}_{amb} + [ ( NOCT - 20 ° C . ) / 0.8 ] \times S$$

where, T_{cell} is cell temperature (° C.), T_{amb} is ambient temperature, and S is solar insolation (kW/m2). This T_{cell} value may then be used in the following equation to derive a derate factor for the predetermined location at particular hours on particular dates:

$$Decrease in {P}_{max} = Temp . Coeff . of {P}_{max} ( \% / ° C . ) \times ( {T}_{cell} - STC cell temperature )$$

$$NOCT derate = 1 - Decrease in {P}_{max} ( \% )$$

where the temperature coefficient of Pₘₐₓ (%/° C.) and the standard test condition (STC) cell temperature may be provided in the manufacturer's PV collector performance data sheet or may be determined from independent testing of the particular collector.

The insolation losses due to derating can then be computed by, for example, taking the TMY hourly insolation amounts and calculating the amount lost due as a factor of NOCT derate. As with the other data, the daily average derating insolation loss value can be calculated by obtaining full (or partial) year data from as many sample points as deemed appropriate or accurate and dividing by the total days, although other methods can be used as well. In the example described herein, a daily average NOCT derate was found of 0.92, resulting in a daily average temperature derating insolation loss of 0.41 kWh/m2/day (5.13×0.08).

At step 108, the daily average effective insolation value for the predetermined location and predetermined orientation of the at least one collector of the PV solar system may be calculated. Specifically, the daily average shading insolation loss value and the daily average temperature derating insolation loss value may both be subtracted from the daily average TMY insolation value. In the example provided herein, the daily average effective insolation value for the predetermined location is 3.24 kWh/m2/day (5.13-1.48-0.41). It should be noted that although step 108 is shown and described as a discrete step, subtraction of the shading and derating losses may be accounted for and subsumed within the previous steps, e.g., the daily average TMY insolation may be multiplied by the NOCT derate and then the shading loss insolation value may be subtracted from the resultant value to obtain the daily average effective insolation value, although other mathematical variations that effectively result in the subtraction of the shading and derating losses from the TMY insolation may be used as well.

At step 110, a minimum energy output requirement for the PV solar system may be determined. For example, historical consumed energy by the infrastructure intended to be powered by the PV solar system may be averaged to estimate a minimum energy output requirement. This average may supplemented to provide a buffer to account for expected overages. In other examples, the historical data may provide a maximum usage, which can be set as the minimum energy output requirement. Other methods of analyzing historical energy data and determining a minimum energy output requirement may be performed as well, including circumstances where the PV solar system may not be required to provide the entire energy supply. In some other embodiments, there may not be historical consumption data to analyze, such as where a new residential or commercial facility is being built, or the like. In these cases, the minimum energy output requirement will have to be estimated based on expected power consumption device installations (e.g., appliances, outlets, computers, servers, or like powered devices), hours of expected operation, similar-sized facility consumption, neighboring consumption, and other like factors. Although step 110 is shown in FIG. 1 as being performed after steps 102-108, it is also possible to perform step 110 prior to computing insolation data. In the example described herein, a minimum energy output requirement may be calculated as 1,200,000 kWh/y.

At step 112, a minimum required PV area for the at least one collector of the PV solar system may be determined, based on the minimum energy output requirement and the daily average effective insolation value. For example, the following equations may be used to compute the required minimum area A:

$$A ( {m}^{2} ) = {P}_{DC} / ( 1 {kWm}^{2} \times η )$$

$${P}_{DC} ( kW ) = Energy ( kWh / yr ) / ( daily avg . eff . insol \times 365 d / yr )$$

where, P_{DC} is the required DC power delivered by the solar arrays, and η is the collectors' manufacturer's efficiency rating.

Using the example described herein, the minimum required amount of power needed to be generated by the PV solar system to meet the minimum energy output requirement is 1014.71 kW (1,200,000/(3.24×365)). Using a collector with a high efficiency rating of 21.7% as an example, the minimum required PV area in this example would be 4676.10 m² (1014.71/(1×0.217)).

At step 114, the PV solar system may be designed and built at the predetermined location with the at least one collector of the PV solar system having at least the minimum required PV area. This step may include a determination of the number of collectors required based on the standard sizes provided by the manufacturer of the selected collector modules. The collector area may exceed the calculated minimum required PV area to account for, for example, malfunctions of cells within a collector, unexpected consumption surges, or the like.

In addition to the above for building the PV solar system, the calculations described above in connection with the method 100 can be put to further use for other purposes, such as economic feasibility studies. For example, with the known minimum required PV area and the minimum energy output requirement, annualized costs, levelized cost of energy, energy payback time and the like may be determined.

Those skilled in the art will recognize that boundaries between the above-described operations are merely illustrative. The multiple operations may be combined into a single operation, a single operation may be distributed in additional operations and operations may be executed at least partially overlapping in time. Further, alternative embodiments may include multiple instances of a particular operation, and the order of operations may be altered in various other embodiments.

While specific and distinct embodiments have been shown in the drawings, various individual elements or combinations of elements from the different embodiments may be combined with one another while in keeping with the spirit and scope of the invention. Thus, an individual feature described herein only with respect to one embodiment should not be construed as being incompatible with other embodiments described herein or otherwise encompassed by the invention.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined herein.

I claim:

1. A method for designing and building a photovoltaic (PV) solar system at a predetermined location, the PV solar system including at least one collector, the method comprising:
calculating a daily average typical meteorological year (TMY) insolation value from TMY data for a predetermined orientation of the at least one collector of the PV solar system;
calculating a daily average shading insolation loss value for the predetermined location resulting from one or more shading obstructions and the predetermined orientation of the at least one collector of the PV solar system;
calculating a daily average temperature derating insolation loss value at the predetermined location;
calculating a daily average effective insolation value for the predetermined location and predetermined orientation of the at least one collector of the PV solar system by subtracting the daily average shading insolation loss value and the daily average temperature derating insolation loss value from the daily average TMY insolation value;
determining a minimum energy output requirement for the PV solar system;
determining a minimum required PV area for the at least one collector of the PV solar system based on the minimum energy output requirement and the daily average effective insolation value; and
building the PV solar system at the predetermined location with the at least one collector at the predetermined orientation, the at least one collector of the PV solar system having at least the minimum required PV area.

2. The method of claim 1, wherein the TMY data includes at least Global Horizontal Irradiance (GHI), Direct Normal Irradiance (DNI), and Diffuse Horizontal Irradiance (DHI) for a latitude and longitude of the predetermined location on at least one selected day of the year at one or more selected hours of the selected day.

3. The method of claim 2, wherein calculating the daily average TMY insolation value includes calculating a total radiation on the at least one collector I_{C} by summing a direct beam radiation I_{BC} on the at least one collector, a diffused radiation I_{DC} on the at least one collector, and a reflected radiation I_{RC} on the at least one collector, wherein I_{BC} is dependent upon DNI, I_{DC} is dependent upon DHI, and I_{RC} is dependent upon GHI.

4. The method of claim 1, wherein the predetermined orientation of the at least one collector of the PV solar system is a fixed orientation wherein the at least one collector fixedly faces a single, predetermined direction and is fixedly angled with respect to a local horizon at a predetermined collector tilt angle.

5. The method of claim 1, wherein the predetermined orientation of the at least one collector of the PV solar system is a one-axis track, wherein the PV solar system moves the at least one collector in a single axis to track a position of the sun in a generally east-west trajectory.

6. The method of claim 1, wherein the predetermined orientation of the at least one collector of the PV solar system is a two-axis track, wherein the PV solar system moves the at least one collector in two axes to track a position of the sun in a generally east-west trajectory and a generally north-south trajectory.

7. The method of claim 1, wherein calculating the daily average shading insolation loss value includes:
determining an azimuth angle and altitude angle for each of the one or more shading obstructions, and
determining one or more time periods, by comparing the azimuth angle and altitude angle of each of the one or more shading obstructions to a sun path for the predetermined location on at least one selected day of the year for one or more selected hours of the selected day, in which the at least one collector of the PV solar system is blocked by shading from each of the one or more shading obstructions.

8. The method of claim 1, wherein calculating the daily average temperature derating insolation loss value is based on at least a nominal operating cell temperature (NOCT) of the at least one collector and ambient temperature for the predetermined location on at least one selected day of the year for one or more selected hours of the selected day.
